(19) United States
(12) Patent Application Publication
(10) Pub. No.: US 2010/0193023 A1
(43) Pub. Date: Aug. 5, 2010

(54) PHOTOVOLTAIC MODULES COMPRISING PLASTICIZED FILMS BASED ON POLYVINYL ACETAL HAVING A HIGH SPECIFIC RESISTANCE

(75) Inventors: Andreas Karpinski, Odenthal (DE); Uwe Keller, Bonn (DE); Martin Steuer, Liederbach (DE); Holger Stenzel, Hennef (DE)

Correspondence Address: BROOKS KUSHMAN P.C., 1000 TOWN CENTER, TWENTY-SECOND FLOOR, SOUTHFIELD, MI, 48075, US

(73) Assignee: KURARAY EUROPE GMBH, Frankfurt am Main (DE)

(21) Appl. No.: 12/680,139

(22) PCT Filed: Oct. 6, 2008
(86) PCT No.: PCT/EP08/63303

§ 371 Date: Mar. 25, 2010

(30) Foreign Application Priority Data
Oct. 5, 2007 (DE) 10 2007 000 816.5

(51) Int. Cl. H01L 31/0203; H01L 31/18

(52) U.S. Cl. 136/256; 438/64; 257/E31.117

(57) ABSTRACT

Plasticizer-containing films based on polyvinyl acetal having a glass transition temperature Tg of at least 20° C. are useful for the production of photovoltaic modules. The films preferably have a plasticizer content of a maximum of 26% by weight.

### TECHNICAL FIELD

The invention relates to the production of photovoltaic modules using plasticizer-containing films based on polyvinyl acetal having high resistivity.

### PRIOR ART

Photovoltaic modules consist of a photosensitive semiconductor layer that is provided with a transparent covering as a protection against external effects. As photosensitive semiconductor layer, monocrystalline solar cells or supported polycrystalline, thin semiconductor layers can be used. Thin-film solar modules consist of a photosensitive semiconductor layer applied to a mostly transparent sheet by means of for example evaporation coating, chemical vapor deposition, sputtering, or wet deposition.

Both systems are normally laminated between a glass panel and a rigid, back covering panel made for example of glass or plastics by means of a transparent adhesive.

The transparent adhesive must completely enclose the photosensitive semiconductor layer and its electrical interconnections, must be UV stable and moisture insensitive, and must be completely bubble-free after the lamination process.

As transparent adhesive, thermosetting casting resins or crosslinkable, ethylene vinyl acetate- (EVA)-based systems are often used, such as for example disclosed in DE 41 22 721 C1 or DE 41 28 766 A1. In the uncured state, these adhesive systems can be adjusted to such a low viscosity that they enclose the solar cell units bubble-free. After addition of a curing or crosslinking agent, a mechanically robust adhesive layer is obtained. A disadvantage of these adhesive systems is that during the curing process, aggressive substances, such as acids, which may destroy the photosensitive semiconductor layers, in particular thin-film modules, are often released. In addition, some casting resins tend to form bubbles or delaminate after a few years as a result of UV radiation.

An alternative to thermosetting adhesive systems is the use of plasticizer-containing films based on polyvinyl acetals, such as polyvinyl butyral (PVB) known from the manufacturing of laminated glass. The solar cell units are covered with one or more PVB films, and the films are bonded with the desired covering materials to a laminate under elevated pressure and temperature.

Methods for the production of solar modules using PVB films are known for example from DE 40 26 165 C2, DE 42 278 60 A1, DE 29 237 70 C2, DE 35 38 986 C2, or U.S. Pat. No. 4,321,418. The use of PVB films in solar modules as laminated safety glass is disclosed for example in DE 20 302 045 U1, EP 1617487 A1, and DE 35 389 86 C2. These documents, however, do not contain any information about the mechanical, chemical, and electrical properties of the PVB films used.

The electrical properties of the adhesive films in particular become more and more important with increasing efficiency of the photosensitive semiconductor layers and global distribution of solar modules. Loss of charge or even short circuits of the semiconductor layer must also be avoided under extreme weather conditions, such as tropical temperatures, high humidity, or heavy UV radiation, over the entire lifetime of the module. According to CEI 61215, photovoltaic modules are subjected to numerous tests (damp heat test, wet leakage current test) in order to reduce leakage currents of the modules. In order to achieve this, the adhesive films need to have a resistivity that is as high as possible.

### OBJECT

Object of the present invention is therefore to provide plasticizer-containing films based on polyvinyl acetal having high (electrical) resistivity for the production of photovoltaic modules.

Surprisingly, it was found that films having an elevated glass transition temperature Tg have increased resistivity. Without being bound to the correctness of the theory, this is attributed to reduced ion mobility in a glass-like or highly viscous environment.

### PRESENTATION OF THE INVENTION

Subject matter of the present invention is therefore photovoltaic modules comprising a laminate of

a) a transparent front covering
b) one or more photosensitive semiconductor layers
c) at least one plasticizer-containing film based on polyvinyl acetal, and
d) a back covering,
the plasticizer-containing films based on polyvinyl acetal
c) having a glass transition temperature Tg of at least 20° C.

The glass transition temperature Tg of the films used according to the invention is preferably in each case at least 22° C., 24° C., 26° C., 27° C., 30° C., or 35° C. 40° C. can be specified as maximum for the glass transition temperature Tg.

The glass transition temperature Tg of plasticizer-containing films based on polyvinyl acetal is largely determined by the content and the polarity or the plasticizing effect of the plasticizer used. As a result, the resistivity of the film can be adjusted in a simple manner via the plasticizer.

The films used according to the invention preferably exhibit at an ambient humidity of 85% RH at 23° C. a resistivity of at least 1E+11 ohm*cm, preferably at least 5E+11 ohm*cm, preferably 1E+12 ohm*cm, preferably 5E+12 ohm*cm, preferably 1E+13, preferably 5E+13 ohm*cm, preferably 1E+14 ohm*cm. These values should be achieved at any position of the film, in particular in the edge regions of the module.

The films based on plasticizer-containing polyvinyl acetal preferably contain uncrosslinked polyvinyl butyral (PVB) obtained by acetalizing polyvinyl alcohol with butyraldehyde.

The use of crosslinked polyvinyl acetals, in particular crosslinked polyvinyl butyral (PVB), is also possible. Suitable crosslinked polyvinyl acetals are described for example in EP 1527107 B1 and WO 2004/063231 A1 (thermal self-crosslinking of carboxyl group-containing polyvinyl acetals), EP 1606325 A1 (polyvinyl acetals crosslinked with polyaldehydes), and WO 03/020776 A1 (Polyvinyl acetals crosslinked with glyoxylic acid). The disclosure of these patent applications is fully incorporated herein by reference.

It is also possible to perform the acetalization using other or additional aldehydes having 5-10 carbon atoms (such as for example valeraldehyde).

Terpolymers of hydrolyzed vinyl acetate/ethylene copolymers can also be used as polyvinyl alcohol within the scope of the invention. These compounds are normally hydrolyzed to more than 98% and contain 1 to 10% by weight of ethylene-based units (for example type “Exceval” of Kuraray Europe GmbH).

Polyvinyl acetals contain in addition to the acetal units also units resulting from vinyl acetate and vinyl alcohol. The polyvinyl acetals used according to the invention preferably have a polyvinyl alcohol content of less than 21% by weight, less than 18% by weight, less than 16% by weight, or most preferably less than 14% by weight. The polyvinyl alcohol content should not fall below 12% by weight.

The polyvinyl acetate content is preferably below 5% by weight, preferably below 3% by weight, and most preferably below 2% by weight. From the polyvinyl alcohol content and the residual acetate content, the degree of acetalization can be calculated.

The high resistivity of the films required according to the invention may be adjusted by means of the type and/or quantity of the plasticizer.

The films preferably have a plasticizer content of a maximum of 26% by weight, more preferably a maximum of 24% by weight, and most preferably a maximum of 22% by weight; for reasons of the processability of the film, the plasticizer content should not fall below 15% by weight. Films or photovoltaic modules according to the invention can contain one or more plasticizers.

Particularly suitable according to the invention are plasticizers, the polarity of which, expressed by the formula 100×O/(C+H), is less than/equal to 9.4; 0, C, and H representing the number of oxygen, carbon, and hydrogen atoms in the respective molecule. The following table shows plasticizers applicable according to the invention and polarity values thereof in accordance with the formula 100×O/(C+H).

| Name | Abbreviation | 100 × O/(C + H) |
|---|---|---|
| Di-2-ethylhexyl sebacate | (DOS) | 5.3 |
| Di-2-ethylhexyl adipate | (DOA) | 6.3 |
| Di-2-ethylhexyl phthalate | (DOP) | 6.5 |
| Dihexyl adipate | (DHA) | 7.7 |
| Dibutyl sebacate | (DBS) | 7.7 |
| Di-2-butoxy-ethyl sebacate | (DBES) | 9.4 |
| Triethylene glycol bis-2-ethyl | (3G8) | |
| hexanoate | | 9.4 |
| 1,2-Cyclohexane dicarboxylic | (DINCH) | |
| acid diisononyl ester | | 5.4 |

Less suitable are the following plasticizers

| Name | Abbreviation | 100 × O/(C + H) |
|---|---|---|
| Triethylene glycol bis-n- | 3G7 | 10.3 |
| heptanoate | | |
| Tetraethylene glycol bis-n- | 4G7 | 10.9 |
| heptanoate | | |
| Di-2-butoxy-ethyl adipate | DBEA | 11.5 |
| Di-2-butoxy-ethoxy-ethyl | DBEEA | 12.5 |
| adipate | | |

The adherence of polyvinyl acetal films to glass is usually adjusted by adding adhesion regulators such as for example the alkaline and/or alkaline earth salts of organic acids disclosed in WO 03/033583 A1. Potassium acetate and/or magnesium acetate turned out to be particularly suitable.

Moreover, polyvinyl acetals often contain from the production process alkaline and/or alkaline earth salts of inorganic acids, such as for example sodium chloride.

Since salts also have an influence on the resistivity, the use of plasticizer-containing films based on polyvinyl acetal having less than 50 ppm, more preferably having less than 30 ppm, and most preferably having less than 20 ppm of metal ion is advantageous. This can be achieved by means of appropriate washing processes of the polyvinyl acetal and by using particularly effective antiblocking agents such as the magnesium, calcium, and/or zinc salts of organic acids (for example acetates) known to those skilled in the art.

Furthermore, the ion mobility, which might depend on the water content of the film, and hence the resistivity can be affected by the addition of pyrogenic silica. The plasticizer-containing films based on polyvinyl acetal preferably contain 0.001 to 15% by weight, preferably 2 to 5% by weight, of pyrogenic SiO₂.

The production and composition of films based on polyvinylacetals is described in principle for example in EP 185 863 B1, EP 1 118 258 B1, WO 02/102591 A1, EP 1 118 258 B1, or EP 387 148 B1.

The lamination of the photovoltaic modules occurs by fusing the films, so that a bubble-free and waviness-free enclosure of the photosensitive semiconductor layer is obtained with the films.

In one variant of the photovoltaic modules according to the invention, the photosensitive semiconductor layers are applied to the covering d) (for example by evaporation coating, chemical vapor deposition, sputtering, or wet deposition) and bonded to the transparent front covering a) by means of a film c).

In another variant, the photosensitive semiconductor layers are applied to the transparent front covering a) and bonded to the back covering d) by means of film c).

Alternatively, the photosensitive semiconductor layers can be embedded between two films c) and bonded to the coverings a) and d) in this manner.

The thickness of the plasticizer-containing films based on polyvinyl acetal is usually 0.38, 0.51, 0.76, 1.14, 1.52, or 2.28 mm.

During the lamination process, films used according to the invention fill the voids existing at the photosensitive semiconductor layers or the electrical connections thereof.

The transparent front covering a) normally consists of glass or PMMA. The back covering d) (so-called back sheet) of the photovoltaic module according to the invention can consist of glass, plastic, or metal or composites thereof, one of the supports possibly being transparent. It is also possible to design one or both of the coverings as laminated glass (i.e. as laminate made of at least two glass panels and at least one PVB film) or as insulation glass with a gas interspace. Naturally, combination of these measures is also possible.

The photosensitive semiconductor layers used in the modules do not need to have any special properties. Monocrystalline, polycrystalline, or amorphous systems can be used.

In case of thin-film solar modules, the photosensitive semiconductor layer is directly applied to the support. An encapsulation is not possible here. For this reason, the composite is assembled from a support (for example the back covering) with the photosensitive semiconductor layer and the transparent front covering using at least one sandwiched plasticizer-containing film based on polyvinyl acetal according to the invention and bonded by means of this film at an elevated temperature. Alternatively, the photosensitive semiconductor layer can be applied to the transparent front covering as support and bonded to the back covering by means of at least one sandwiched plasticizer-containing film based on polyvinyl acetal according to the invention.

For lamination of the composite thus obtained, the methods known to those skilled in the art can be used with or without prior making of a pre-laminate.

So-called autoclave processes are performed at an elevated pressure of approximately 10 to 15 bar and temperatures of 130 to 145° C. over the course of approximately 2 hours. Vacuum bag or vacuum ring methods, for example according to EP 1 235 683 B1, operate at approximately 200 mbar and 130 to 145° C.

Vacuum laminators are preferably used for the production of the photovoltaic modules according to the invention. They consist of a heatable and evacuateable chamber, wherein laminated glasses may be laminated within 30-60 minutes. Reduced pressures of 0.01 to 300 mbar and temperatures of 100 to 200° C., most preferably 130-160° C., have proven to be of value in practice.

Alternatively, a composite assembled as described above can be pressed into the module according to the invention between at least one pair of rollers at a temperature of 60 to 150° C. Installations of this kind are known for the production of laminated glasses and usually have at least one heating tunnel upstream or downstream from the first pressing apparatus in installations having two pressing apparatuses.

A further subject matter of the invention is the use of plasticizer-containing films based on polyvinyl acetal having a glass transition temperature Tg of at least 20° C. for the production of photovoltaic modules.

Photovoltaic modules according to the invention can be used as facade element, roof areas, winter garden covering, sound insulating wall, balcony or balustrade element, or as component of window areas.

### MEASURING PROCEDURES

The determination of the glass transition temperature of the film is performed by means of Differential Scanning Calorimetry (DSC) in accordance with DIN 53765 using a heating rate of 10 K/min in a temperature interval of −50° C.-150° C. A first heating ramp, followed by a cooling ramp, followed by a second heating ramp is used. The position of the glass transition temperature is determined from the measured curve associated with the second heating ramp in accordance with DIN 51007. The DIN midpoint (Tg DIN) is defined as intersection of a horizontal line at half step height with the measured curve. The step height is defined by the vertical distance of the two intersections of the middle tangent with the base lines of the measured curve before and after the glass transition.

The determination of the flow behavior of the film takes place as melt-flow index (melt mass flow rate: MFR) in accordance with ISO 1133 on a suitable instrument, for example from Göttfert Company, Model MI2. The MFR value is specified at 100° C. and 140° C. with the 2 mm nozzle and a weight loading of 21.6 kg in gram per 10 minutes (g/10 min).

The measurement of the volume resistivity of the film is performed in accordance with DIN IEC 60093 at a defined temperature and ambient humidity (23° C. and 85% RH) after the film has been conditioned for at least 24 h under these conditions. For the execution of the measurement, a plate electrode of type 302 132 from the company Fetronic GmbH and an instrument for resistivity measurement ISO-Digi 5 kV from Amprobe Company was used. The testing voltage was 2.5 kV, the wait time after application of the testing voltage until acquisition of measured data was 60 sec. In order to guarantee sufficient contact between the flat plates of the measuring electrode and the film, the surface roughness R_{z} of the film should not be greater than 10 μm when measuring in accordance with DIN EN ISO 4287; i.e. the original surface of the PVB film has to be smoothed by thermal reembossing prior to the resistivity measurement, if necessary.

The polyvinyl alcohol and polyvinyl acetate contents of the polyvinyl acetals were determined in accordance with ASTM D 1396-92. Analysis of the metal ion content took place by means of atomic absorption spectroscopy (AAS).

The water or moisture content of the films is determined by the Karl Fischer method. In order to simulate the moistening behavior under humid conditions, the film is stored beforehand for 24 h at 23° C. and 85% RH. The method can be performed on both the unlaminated film and a laminated photovoltaic module as a function of the distance to the edge of the film.

### EXAMPLES

Mixtures of the composition listed in Table 1 were produced and tested for glass transition temperature Tg, flowability, and electrical resistivity.

DBEEA means di-2-butoxy-ethoxy-ethyl adipate

DBEA means di-2-butoxy-ethyl adipate

3G8 means triethylene glycol bis-2-ethyl hexanoate

Mowital PVB means high-viscosity polyvinyl butyral having a viscosity of 60-90 mPas (measured in accordance with DIN 53015 as 5% solution in ethanol (with 5% of water) at 20° C.); polyvinyl alcohol content: 20.3% by weight; polyvinyl acetate content: 1.1% by weight; degree of acetalization: 78.6%

It becomes apparent that standard films with medium plasticizer content (Comp. Ex. 1) exhibit a resistance that is too low for photovoltaic applications. Film mixtures with high plasticizer content (Comp. Ex. 2) have indeed high flowability, but also a low glass transition temperature Tg and hence even lower resistivity.

Reducing the plasticizer content (Ex. 1) causes a significant increase of the glass transition temperature and resistivity. This can, besides increasing the flowability by using plasticizers of low polarity (Ex. 2 vs. Ex. 1), be further improved.

Ex. 1 and 2 show that an improvement of the resistivity can be achieved by means of the films with increased glass transition temperature Tg used according to the invention.

Films of this type are suitable for photovoltaic applications.

TABLE 1

| | | Comp. Ex. 1 | Comp. Ex. 2 | Ex. 1 | Ex. 2 |
|---|---|---|---|---|---|
| Composition | | | | | |
| MOWITAL PVB | wt.-% | 72.5 | 65 | 80 | 80 |
| Plasticizer 3G8 | wt.-% | 25 | 17.5 | 10 | 20 |
| Plasticizer DBEA | wt.-% | 2.5 | — | — | — |
| Plasticizer DBEEA | wt.-% | — | 17.5 | 10 | — |
| Total plasticizer content | wt.-% | 27.5 | 35 | 20 | 20 |
| Characterization | | | | | |
| Water content of film | wt.-% | 0.43 | 0.43 | 0.50 | 0.45 |
| Melt flow index MFR 21.6/100/2 | g/10 min | 0.22 | 1.90 | 0.13 | 0.13 |
| Melt flow index MFR 21.6/140/2 | g/10 min | 8.7 | 48.2 | 4.6 | 4.3 |
| Glass transition temperature Tg | ° C. | 18.3 | 7.4 | 25.5 | 27.9 |
| (DSC) | | | | | |
| Electrical Resistivity | Ohm * cm | 1.09E+12 | 1.09E+10 | 6.20E+12 | 5.20E+13 |

1.-10. (canceled)

11. A photovoltaic module comprising a laminate of
a) a transparent front covering
b) one or more photosensitive semiconductor layers
c) at least one plasticizer-containing film based on polyvinyl acetal, and
d) a back covering,
wherein the plasticizer-containing films based on polyvinyl acetal c) have a glass transition temperature Tg of at least 20° C.

12. The photovoltaic module of claim 11, wherein the plasticizer-containing films based on polyvinyl acetal c) have a plasticizer content of a maximum of 26% by weight.

13. The photovoltaic module of claim 11 wherein the polyvinyl acetal has a polyvinyl alcohol content of less than 21% by weight.

14. The photovoltaic module of claim 11, wherein the polyvinyl acetal has a polyvinyl acetate content of less than 5% by weight.

15. The photovoltaic module of claim 11, wherein one or more compounds, the polarity of which, expressed by the formula 100×O/(C+H), is less than/equal to 9.4, O, C, and H representing the number of oxygen, carbon, and hydrogen atoms in the respective molecule, are used as plasticizer.

16. The photovoltaic module of claim 11, wherein one or more compounds selected from the group consisting of di-2-ethylhexyl sebacate, di-2-ethylhexyl adipate, di-2-ethylhexyl phthalate, dihexyl adipate, dibutyl sebacate, di-2-butoxy-ethyl sebacate, 1,2-cyclohexane dicarboxylic acid diisononyl ester, and triethylene glycol bis-2-ethyl hexanoate are used as plasticizer.

17. The photovoltaic module of claim 11, wherein the plasticizer-containing film based on polyvinyl acetal contains less than 50 ppm of metal ions.

18. The photovoltaic module of claim 11, wherein the plasticizer-containing film based on polyvinyl acetal contains 0.001 to 5% by weight of SiO₂.

19. The photovoltaic module of claim 11, wherein polyvinyl butyral is used as the polyvinyl acetal.

20. In the production of a photovoltaic module wherein plastic film is employed, the improvement comprising employing a plasticizer-containing film comprising polyvinyl acetal having a glass transition temperature Tg of at least 20° C.
